(19) United States
(12) Patent Application Publication
(10) Pub. No.: US 2020/0146173 A1
(43) Pub. Date: May 7, 2020

(54) Connection Device Between Rail and Rack Post of Server Cabinet

(71) Applicant: Chi Feng Hsu, New Taipei City (TW)

(72) Inventor: Chi Feng Hsu, New Taipei City (TW)

(21) Appl. No.: 16/178,453

(22) Filed: Nov. 1, 2018

(51) Int. Cl. H05K 7/18

(52) U.S. Cl. CPC H05K 7/183

(57) ABSTRACT

A connection device between a rail and rack posts of a server cabinet includes three connection units and each connection unit connects the rail to the rack post. The first connection unit uses a fixing member securely connected to a plate so as to connect the plate to the rack post. The second connection unit uses a locking member which has a hook, and the hook is engaged with a slot defined in a pin extending through the rack post. The third connection unit includes a securing member and a locking bolt respectively locate don two sides of the bracket of the rail. The bracket of the rail includes elongate hole so that the securing member is movably positioned by the locking bolt. The three connection units meet different requirements when connecting a rail to the rack posts.

### BACKGROUND OF THE INVENTION

### 1. Fields of the Invention

The present invention relates to a connection device, and more particularly, to a connection device between rail and rack post of a server cabinet.

### 2. Descriptions of Related Art

A conventional way to storage and manage servers is to use a cabinet which includes multiple rails connected between rack posts in the cabinet, the rails are designed to be easily assembled and dis-assembled relative to the rack posts. The servers are positioned on the rails and organized for having optimal storage and maintenance features.

The present invention is intended to provide three different connection devices that can be used to achieve the above-mentioned purposes.

### SUMMARY OF THE INVENTION

The present invention relates to a connection device between rail and rack post of a server cabinet, and comprises a first connection unit having a fixing member which includes a bent portion and multiple first holes. A plate includes an aperture and multiple second holes, wherein the bent portion of the fixing member extends through the aperture of the plate, and the first holes of the fixing member are located corresponding to the second holes of the plate. Multiple bolts extend through the second holes and connected to the first holes. A pressing portion protrudes from one side of the plate and is located corresponding to one inner end of the aperture so as to press on the bent portion.

The present invention also provides a second connection unit that has a locking member, a spring, a pivot and a pin. The locking member has an end portion on the first end thereof, and a hook on the second end thereof. A fastening portion is located between the end portion and the hook. The spring has a first end and a second end, wherein the first end of the spring is engaged with the locking member, and the second end of the spring is engaged with a rail. The pivot extends through the fastening portion and are connected to the rail. The pin has a slot defined in one end and opens through a periphery thereof, and the hook is inserted into the slot.

Preferably, the locking member is pivotable about the pivot. The hook of the locking member extends through the slot of the pin and hooks to a rack post.

The present invention further provides a third connection unit that comprises a securing member, a locking bolt and a contact plate. The securing member has a tubular portion extending from one end thereof, and a threaded hole is defined axially in the tubular portion. The tubular portion of the securing member extends through a positioning hole defined through a rail. The locking bolt extends through the positioning holes of the rail and is connected to the securing member. The positioning hole of the rail is an elongate hole.

Preferably, the tubular portion of the securing member is movably positioned between two inner ends of the positioning hole.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 shows the three connection units of the present invention used on a rail and a rack post;

FIG. 2 is an exploded view of the first connection unit of the present invention;

FIG. 3 is an exploded view of the second connection unit of the present invention;

FIG. 4 is an exploded view of the third connection unit of the present invention;

FIG. 5 is cross sectional view of the first connection unit of the present invention;

FIG. 6 shows the plate is fixed to the rack post by the first connection unit of the present invention;

FIG. 7 is a cross sectional view to show the second connection unit of the present invention is to connect a rail to a rack post;

FIG. 8 is a cross sectional view to show the second connection unit of the present invention connects the rail to the rack post in FIG. 7, and

FIG. 9 shows that the securing member is movably position relative to the elongate positioning hole of the rail.

### DETAILED DESCRIPTION OF THE PREFERRED EMBODIMENT

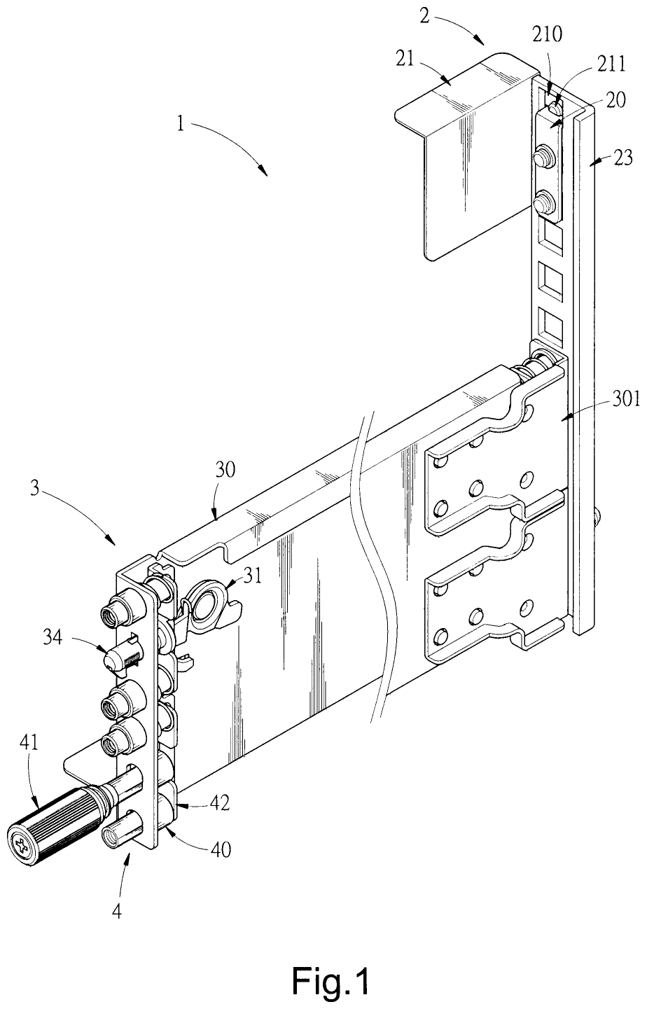

Referring to FIG. 1, the connection device 1 of the present invention includes a first connection unit 2, a second connection unit 3 and a third connection unit 4.

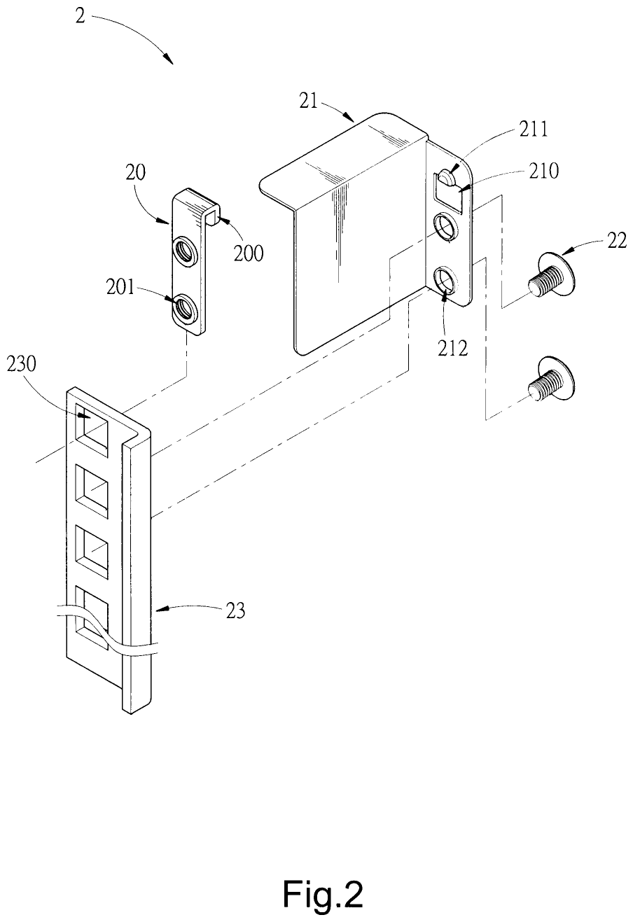

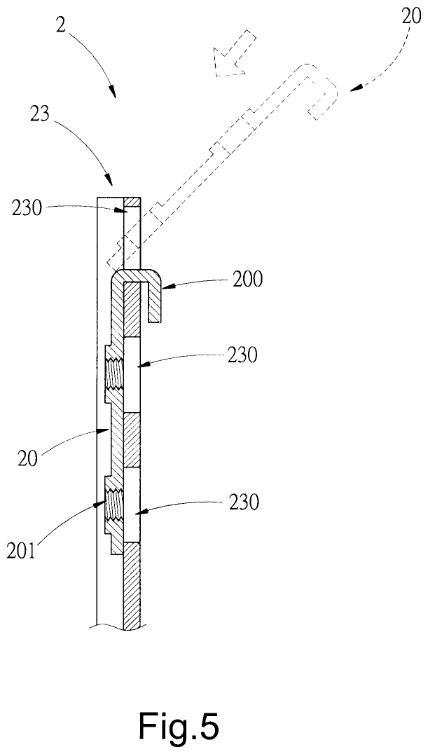

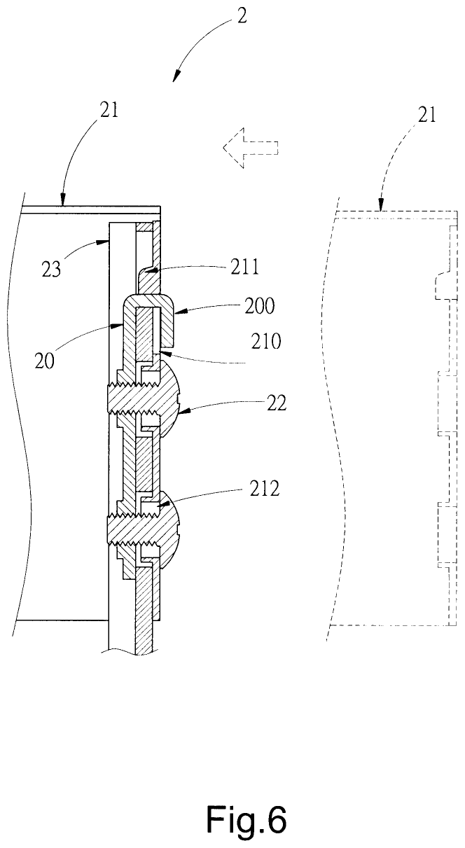

Referring to FIGS. 1, 2, 5 and 6, the first connection unit 2 comprises a fixing member 20, a plate 21 and multiple bolts 22. The fixing member 20 includes a bent portion 200 formed on one end thereof, and multiple first holes 201 are defined through the fixing member 20. The plate 21 has an aperture 210 and multiple second holes 212 defined through a bent end thereof. As shown in FIG. 5, the fixing member 20 extends through the connection hole 230 of the rack post 23 at an angle, and the bent portion 200 of the fixing member 20 hangs the fixing member 20 on one side of the rack post 23. The first holes 201 of the fixing member 20 are located corresponding to the connection holes 230 of the rack post 23. The bent end of the plate 21 is then located on the other side opposite to the fixing member 20, and the first holes 201 of the fixing member 20 are located corresponding to the second holes 212 of the plate 21. A pressing portion 211 protrudes from one side of the plate 21 and located corresponding to one inner end of the aperture 210. The pressing portion 211 presses on the top of the bent portion 200. Multiple bolts 22 extend through the second holes 212 of the plate 21, the connection holes 230 of the rack post 23, and are threadedly connected to the first holes 201 of the fixing member 20. By the first connection unit 2, the plate 21 is secured to the rack post 23 and other part is connected to the plate 21.

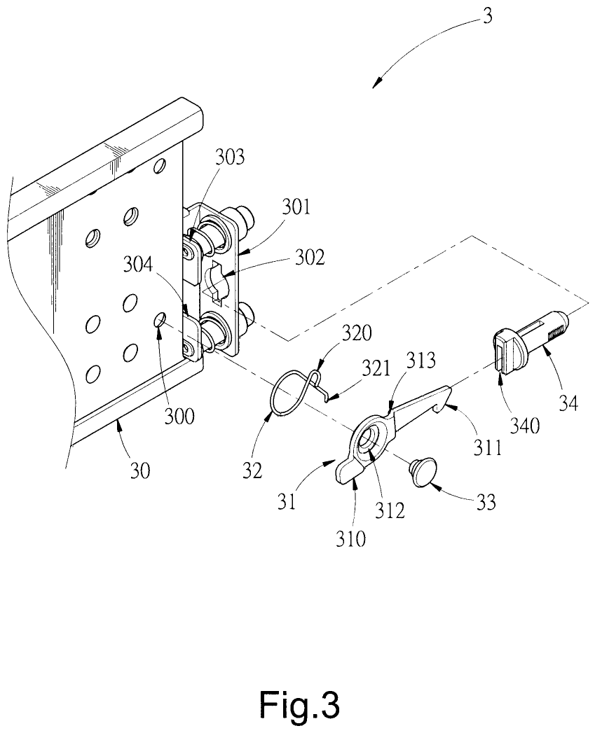

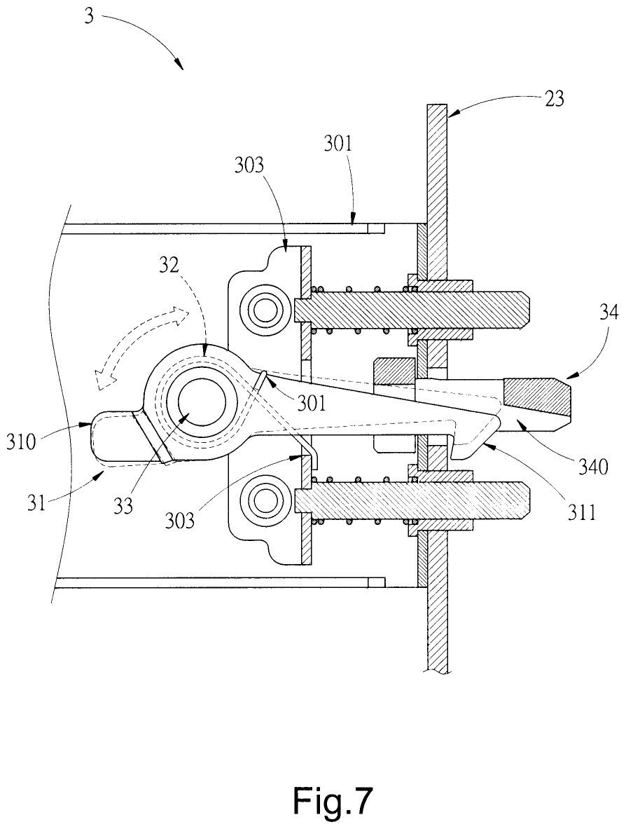

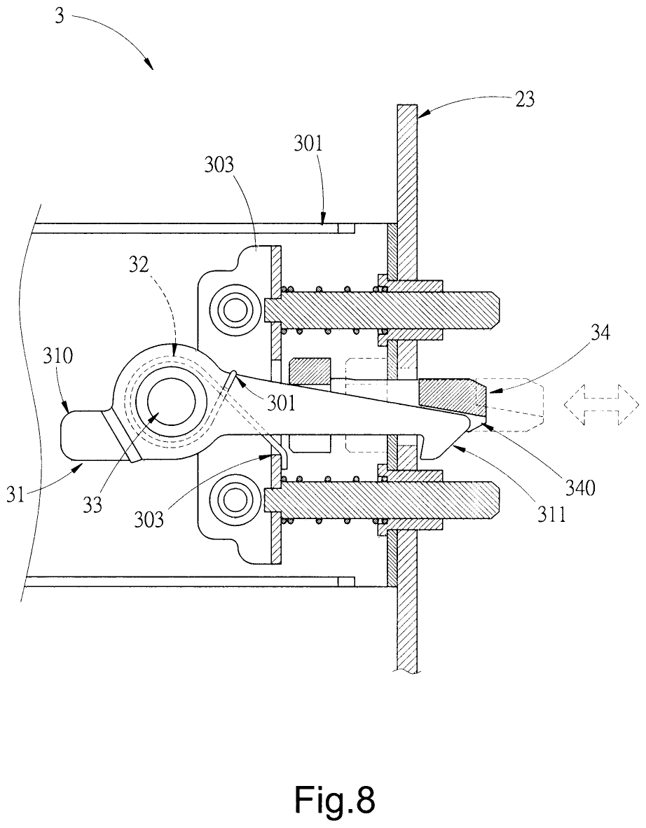

As shown in FIGS. 3, 7 and 8, the second connection unit 3 comprises a locking member 31, a spring 32, a pivot 33 and a pin 34. The locking member 31 has an end portion 310 on the first end thereof, and a hook 311 on the second end thereof. A fastening portion 312 is located between the end portion 310 and the hook 311. The spring 32 is a torsion spring and includes a first end 320 and a second end 321, wherein the first end 320 of the spring 32 is engaged with a first position 313 of the locking member 31, and the second end 321 of the spring 32 is engaged with a second position 304 of a first connection part 303 of a rail 30. The pivot 33 extends through the fastening portion 312 and connected to one of the bores 300 in the rail 30 as shown in FIG. 3. The pin 34 having a slot 340 defined in one end thereof and opens through the periphery of the pin 34 as shown in FIG. 7. The locking member 31 is pivotable about the pivot 33, and the spring 32 can return the locking member 31 back to its initial position. As shown in FIGS. 7 and 8, the hook 311 is inserted into the slot 340 and protrudes beyond the periphery of the pin 34, and the hook 311 also extends through a hole 302 of a second connection part 301. When the rail 30 is located corresponding to the rack post 23, the pin 34 extends through the connection hole of the rack post 23. The hook 311 extends through the connection hole of the rack post and hooks to the rack post 23. The pin 34 is then pushed toward the locking member 31. It is noted that the inside of the slot 340 is tapered as shown in FIG. 8, so that the inside of the slot 340 securely presses the inclined top of the hook 311 to secure the locking member 31. Therefore, the locking member 31 is securely hooks the rack post 23, and the rail 30 is fixed to the rack post 23.

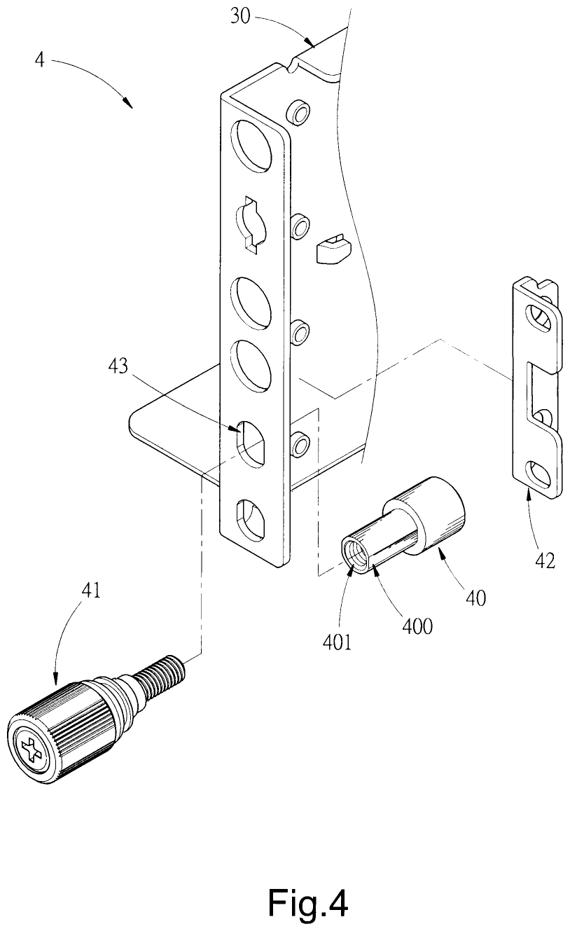

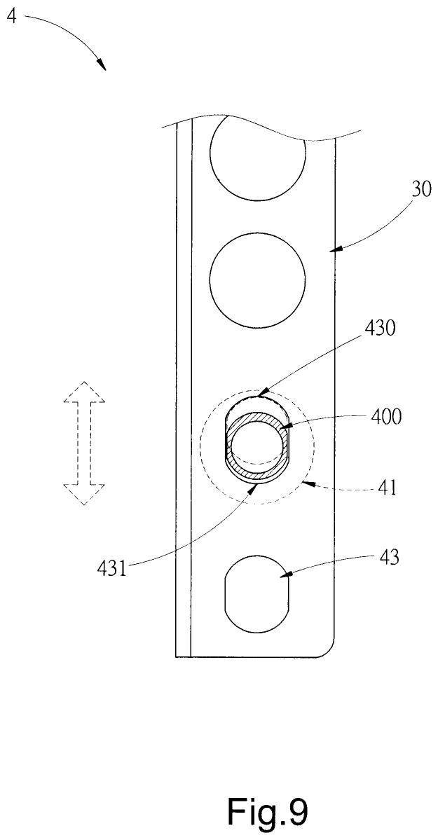

As shown in FIGS. 1, 4 and 9, the third connection unit 4 comprises a securing member 40, a locking bolt 41 and a contact plate 42. The securing member 40 has a tubular portion 400 extending from one end of a head, and a threaded hole 401 is defined axially in the tubular portion 400. The diameter of the head is larger than that of the tubular portion 400. The tubular portion 400 of the securing member 40 extends through a positioning hole 43 defined through a bent end of a rail 30, and the locking bolt 41 extends through the positioning holes 43 of the rail 30 and is connected to the securing member 40. It is noted that the positioning hole 43 of the rail 30 is an elongate hole 43 which includes two inner ends 430 and 431, and a distance is formed between the two inner ends 430, 431. The tubular portion 400 of the securing member 40 is movable between the two inner ends 430, 431, and when the locking bolt 41 is connected to the threaded hole 401, the head contacts against the bent end of the rail 30 so that the securing member 40 is movably positioned between two inner ends 430, 431 of the positioning hole 43 to easily and successfully install the servers of different sizes between rails 30.

While we have shown and described the embodiment in accordance with the present invention, it should be clear to those skilled in the art that further embodiments may be made without departing from the scope of the present invention.

1. A connection device between rail and rack post, comprising:
a first connection unit having a fixing member, a plate and multiple bolts, the fixing member having a bent portion and multiple first holes, the plate having an aperture and multiple second holes, the bent portion of the fixing member extending through the aperture of the plate, the first holes of the fixing member located corresponding to the second holes of the plate, multiple bolts extending through the second holes and connected to the first holes, a pressing portion protruding from one side of the plate and located corresponding to one inner end of the aperture, the pressing portion pressing on the bent portion.

2. A connection device between rail and rack post, comprising:
a second connection unit having a locking member, a spring, a pivot and a pin, the locking member having an end portion on a first end thereof and a hook on a second end thereof, a fastening portion located between the end portion and the hook;
the spring having a first end and a second end, the first end of the spring engaged with the locking member, the second end of the spring adapted to be engaged with a rail, the pivot extending through the fastening portion and the spring, and adapted to be connected to the rail, and
a slot defined in one end of the pin and opening through a periphery of the pin, the hook inserted into the slot.

3. The connection device as claimed in claim 2, wherein the locking member is pivotable about the pivot, the hook of the locking member extends through the slot of the pin and is adapted to hook a rack post.

4. The connection device as claimed in claim 2, wherein the slot of the pin includes a tapered inside, the hook of the locking member is pressed by the tapered inside of the slot when the pin is moved.

5. A connection device between rail and rack post, comprising:
a third connection unit having a securing member, a locking bolt and a contact plate, the securing member having a tubular portion extending from one end thereof, a threaded hole defined axially in the tubular portion, the tubular portion of the securing member extending through a positioning hole defined through a rail, the locking bolt extending through the positioning holes of the rail and connected to the securing member, the positioning hole of the rail being an elongate hole.

6. The connection device as claimed in claim 5, wherein the tubular portion of the securing member is movably positioned between two inner ends of the positioning hole.
